(19) United States
(12) Patent Application Publication
(10) Pub. No.: US 2013/0052774 A1
(43) Pub. Date: Feb. 28, 2013

(54) METHOD FOR SURFACE-TREATING SEMICONDUCTOR SUBSTRATE, SEMICONDUCTOR SUBSTRATE, AND METHOD FOR PRODUCING SOLAR BATTERY

(71) Applicant: Kenichi Kurobe, Kyoto-shi (JP)

(72) Inventor: Kenichi Kurobe, Kyoto-shi (JP)

(73) Assignee: KYOCERA CORPORATION, Kyoto-shi, Kyoto (JP)

(21) Appl. No.: 13/697,227

(22) PCT Filed: Jun. 29, 2011
(86) PCT No.: PCT/JP2011/064921

§ 371 Date: Nov. 9, 2012

(30) Foreign Application Priority Data
Jun. 29, 2010 (JP) 2010-147853

(51) Int. Cl. B08B 3/08; H01L 31/18; H01L 29/02

(52) U.S. Cl. 438/98; 257/798; 134/3; 257/E31.124; 257/E29.002

(57) ABSTRACT

Disclosed is a method for surface-treating a semiconductor substrate to thereby reduce loss of minority carriers caused by surface recombination and improve the lifetime. In the method, a semiconductor substrate is prepared. An acid additive and an alkaline additive are added to water to obtain an aqueous solution having a pH of not more than 7. The aqueous solution comprises no hydrofluoric acid. A dangling bond at a surface of the semiconductor substrate is hydrogen-terminated. The surface, at which the dangling bond has been hydrogen-terminated, is brought into contact with the aqueous solution.

The present invention relates to a method for surface treatment of semiconductor substrate, a semiconductor substrate on which this has been carried out, and a method for manufacturing a solar cell.

### BACKGROUND ART

Large scale integration (LSI) devices, integrated circuits (ICs), diodes, rectifier elements, solar cells, and other such semiconductor devices are manufactured by carrying out vapor phase deposition, oxide film formation, diffusion of dopants, vapor deposition of metal films for electrodes, and other such steps on a semiconductor substrate. At each of these steps, contamination of the semiconductor substrate by metal and/or other impurities will have a marked effect on the electrical properties of the semiconductor device.

It is therefore necessary to adequately clean the surface of the semiconductor substrate and remove contaminants therefrom prior to each of the foregoing steps. As disclosed for example at Japanese Patent Application Publication Kokai No. H5-136112 (1993), cleaning of the semiconductor substrate with pure water might be carried out using warm pure water having a pH of not more than 7.

But even where the foregoing cleaning was carried out, there being no improvement in the lifetime of minority carriers within the semiconductor substrate, it had not been possible to reduce loss of minority carriers due to surface recombination.

### DISCLOSURE OF THE INVENTION

It is an object of the present invention to provide a method for surface treatment of semiconductor substrate, a semiconductor substrate on which this has been carried out, and a method for manufacturing a solar cell that permit reduction in loss of minority carriers due to surface recombination, and that permit improvement in the lifetime of minority carriers.

A method for surface treatment of a semiconductor substrate associated with an embodiment of the present invention comprises a hydrogen treatment step. In the hydrogen treatment step, a dangling bond at a surface of a semiconductor substrate is hydrogen-terminated. The method for surface treatment of the semiconductor substrate further comprises a warm water treatment step. In the warm water treatment step, the surface of the semiconductor substrate at which the dangling bond has been hydrogen-terminated is brought into contact with warm water. An acid additive and an alkaline additive have been added to the warm water. The warm water has a pH of not more than 7.

A semiconductor substrate is associated with an embodiment of the present invention. The method for surface treatment of the semiconductor substrate has been carried out on the semiconductor substrate. The dangling bond at the surface of the semiconductor substrate is hydroxyl-terminated.

A method for manufacturing a solar cell is associated with an embodiment of the present invention. The method for manufacturing the solar cell comprises a substrate preparation step. In the substrate preparation step, a semiconductor substrate for a solar cell is prepared. The prepared semiconductor substrate comprises a semiconductor junction region. The method for surface treatment of the semiconductor substrate has been carried out on the prepared semiconductor substrate. The method for manufacturing the solar cell further comprises an electrode formation step. In the electrode formation step, an electrode for extracting output is formed on the semiconductor substrate.

A method for manufacturing a solar cell is associated with an embodiment of the present invention. The method for manufacturing the solar cell comprises a substrate preparation step. In the substrate preparation step, a semiconductor substrate for a solar cell is prepared. The method for surface treatment of the semiconductor substrate has been carried out on the prepared semiconductor substrate. The method for manufacturing the solar cell further comprises a junction region formation step. In the junction region formation step, the semiconductor substrate is used to form a semiconductor junction region. The method for manufacturing the solar cell further comprises an electrode formation step. In the electrode formation step, an electrode for extracting output is formed on the semiconductor substrate.

The method for surface treatment of semiconductor substrate, the semiconductor substrate on which this has been carried out, and the method for producing a solar cell make it possible to provide a semiconductor substrate and a solar cell that permit reduction in loss of minority carriers due to surface recombination and that permit improvement in lifetime.

### BRIEF DESCRIPTION OF THE DRAWINGS

FIG. 1 is a group of drawings for explaining an example of a method for manufacturing a solar cell (double-sided-electrode solar cell element) according to one embodiment of the present invention, (a) through (e) respectively being sectional schematic views thereof.

FIG. 2 is a group of drawings for explaining an example of a method for manufacturing a solar cell (heterojunction solar cell element) according to one embodiment of the present invention, (a) through (d) respectively being sectional schematic views thereof.

### EMBODIMENTS FOR CARRYING OUT THE INVENTION

Below, embodiments of a method for surface treatment of semiconductor substrate, a semiconductor substrate on which this has been carried out, and a method for manufacturing a solar cell associated with the present invention are described in detail in terms of an example employing a wet treatment method.

Basic steps that are carried out in a method for surface treatment of a semiconductor substrate will first be described.

At least a hydrogen treatment step and a warm water treatment step are carried out on a semiconductor substrate. In the hydrogen treatment step, dangling bonds at the surface of the semiconductor substrate are hydrogen-terminated. At the warm water treatment step, the surface of the semiconductor substrate at which hydrogen termination of dangling bonds was carried out is brought into contact with warm water which has a pH of not more than 7 and which contains acid additive(s) and alkaline additive(s).

Here, it is particularly advantageous if the hydrogen treatment step is carried out by bringing the surface of the semiconductor substrate into contact with hydrofluoric acid solution. Besides hydrofluoric acid solution, this may be carried out by bringing the surface of the semiconductor substrate into contact with buffer solution in which fluoride has been mixed as appropriate, or with a mixed solution containing organic acid(s), inorganic acid(s), and the like which has been prepared for the purpose of removing metal ions.

It is advantageous if the warm water treatment step is carried out by bringing the surface of the semiconductor substrate into contact with warm water having a pH of not less than 5 and not more than 6, and it is even more advantageous if this is carried out by bringing the surface of the semiconductor substrate into contact with warm water that is not less than 80° C. but is less than 100° C. This may be carried out by bringing the surface of the semiconductor substrate into contact with warm water, where the warm water is warm water to which acid additive(s) comprising nitric acid, hydrochloric acid, and/or sulfuric acid and alkaline additive(s) comprising ammonia, ammonium chloride, ammonium nitrate, ammonium sulfate, ammonium carbonate, ammonium hydrogen carbonate, tetramethylammonium hydroxide, and/or potassium cyanide have been added. It is particularly advantageous if this is carried out by bringing the surface of the semiconductor substrate into contact with warm water in which acid additive is present in a concentration that is not less than 1 ppm and not more than 1000 ppm by mass.

Next described are specific steps for carrying out a method for surface treatment of a semiconductor substrate.

As the semiconductor substrate to be prepared, monocrystalline silicon substrate, polycrystalline silicon substrate, germanium substrate, or the like having prescribed dopant element(s) (impurities for controlling charge carrier type) and being of one charge carrier type (e.g., p-type) may be employed.

First, at the hydrogen treatment step, the surface oxide layer (native oxide film) at the semiconductor substrate is removed, and dangling bonds at the surface of the semiconductor substrate are terminated with hydrogen. As the foregoing treatment method, wet etching treatment and/or dry etching treatment is employed. In wet etching treatment, dangling bonds at the surface of the semiconductor substrate might, for example, be hydrogen-terminated by immersing the semiconductor substrate in hydrofluoric acid solution. Here, it is preferred that concentration of the hydrofluoric acid solution be 0.01% to 50% by mass. In dry etching treatment, the surface of the semiconductor substrate is irradiated with hydrogen plasma to remove the surface oxide layer and hydrogen-terminate dangling bonds at the surface of the semiconductor substrate.

Next, at the warm water treatment step, treatment is carried out by immersing the semiconductor substrate for on the order of 10 to 80 minutes in a tank filled with warm water to which acid additive(s) and alkaline additive(s) have been added and which has a pH of not more than 7, causing the surface of the semiconductor substrate to be brought into contact with this warm water.

By carrying out the aforementioned two steps in sequence on the semiconductor substrate, it is possible to reduce loss of minority carriers due to surface recombination, making it possible to extend minority carrier lifetime. It is speculated that the reason for this is that removal of the surface oxide layer and the surface reconstruction layer at the semiconductor substrate, and, e.g., where the semiconductor substrate is bulk crystal, termination of hydroxyl groups at the crystal structure appearing at the surfacemost portion thereof, causes lowering of interface state density and reduction in loss of minority carriers due to surface recombination. “Surface reconstruction layer” refers to a layer which has a structure that is different from the original bulk crystal structure, and includes the outermost layer of the crystal surface and several layers therebelow.

Presence of surface oxide layer and surface reconstruction layer at the semiconductor substrate may be confirmed based on disorder and presence of periodic structure during observation made using a cross-sectional transmission electron microscope (TEM). Termination of hydroxyl groups at the crystal structure may, for example, be confirmed by three-dimensional mapping using a three-dimensional atom probe or the like.

Use of warm water having a temperature which is higher than normal water temperature causes increase in the water ion product, which increases hydroxide ion concentration and promotes termination of hydroxyl groups at the surface of the semiconductor substrate. At the warm water, reduction in the amount of dissolved oxygen permits reduced formation of the surface oxide layer at the semiconductor substrate. Pure water which has been heated is preferably used for the warm water, it being advantageous if the temperature thereof is not less than 80° C. but is less than 100° C. It is more preferred that pure water which has been boiled and degassed be used for the warm water.

Adding acid additive(s) to warm water makes it possible to control the oxidation-reduction potential of the aqueous solution so that it is a value which is suitable for termination of hydroxyl groups at the bulk crystal structure. As the acid additive(s), it is possible to use strong acid(s) comprising nitric acid, hydrochloric acid, and/or sulfuric acid, and/or weak acid(s) comprising acetic acid, formic acid, and/or the like. Strong acid(s) are particularly preferred because their high degree of electrolytic dissociation makes it possible to reduce the amount of acid additive(s) which must be present. Note that hydrofluoric acid is not used as acid additive. The reason is that this would cause the hydroxyl groups to again undergo hydrogen substitution. It is preferred that concentration of acid additive(s) in warm water be not less than 1 ppm and not more than 1000 ppm by mass.

Adding suitable amount(s) of alkaline additive(s) to warm water makes it possible to control the oxidation-reduction potential of the water so that it is a value which is suitable for termination of hydroxyl groups, while at the same time ensuring that an appropriate concentration of hydroxide ions in the warm water can be attained. As a result, this causes, e.g., where silicon material is used as semiconductor substrate, the surface reconstruction layer at the semiconductor substrate to be removed due to reaction between silicon and hydroxide ions (Si+4OH⁻Si(OH)₄+4e⁻). Some of the metal impurities adhering to the semiconductor substrate are removed therefrom as complex ions. As alkaline additive(s), ammonia, ammonium chloride, ammonium nitrate, ammonium sulfate, ammonium carbonate, ammonium hydrogen carbonate, tetramethylammonium hydroxide, and/or potassium cyanide may be used. In particular, use of ammonium carbonate as alkaline additive will permit marked increase in minority carrier lifetime. It is thought that this may be due to hydroxide ions produced by hydrolysis of carbonate ions, which facilitate removal of the surface reconstruction layer at the semiconductor substrate, which contributes to the reaction with the semiconductor substrate. Concentration of alkaline additive(s) is adjusted so as to cause the warm water which contains acid additive(s) and alkaline additive(s) to have a pH that is not more than 7.

When silicon material is used as semiconductor substrate, because silanol groups (Si—OH) formed at the surface of the semiconductor substrate are weakly acidic, causing pH of the warm water to be not more than 7 makes it possible to suppress formation of siloxane bonds (Si—O—Si), and makes it possible to stabilize termination of hydroxyl groups at the surface of the semiconductor substrate.

In particular, because causing pH of the warm water to be not less than 5 and not more than 6 makes it possible to ensure attainment of adequate hydroxide ions in the warm water, this makes it possible to reduce treatment time and to also more stably terminate hydroxyl groups at the surface of the semiconductor substrate.

Next, the semiconductor substrate is extracted from the warm water and is dried. Thereafter, to measure the lifetime of minority carriers within this semiconductor substrate, a lifetime measurement apparatus which utilizes the microwave photoconductivity decay (μ-PCD) technique is employed. As described below, when the foregoing lifetime measurement apparatus was actually used to measure lifetime of minority carriers at this semiconductor substrate, it was found that lifetime was markedly improved as compared with semiconductor substrate which had not undergone the foregoing hydrogen treatment step and warm water treatment step.

By carrying out various steps on such a semiconductor substrate, a semiconductor device may be fabricated. An example of a semiconductor device which may be fabricated is given below.

As semiconductor device, a method for manufacturing a solar cell which is provided with a pn junction region will first be described. A double-sided-electrode solar cell element in which electrodes of mutually differing polarity are arranged over respective principal planes corresponding to the two principal planes of a semiconductor substrate might, for example, be fabricated as follows.

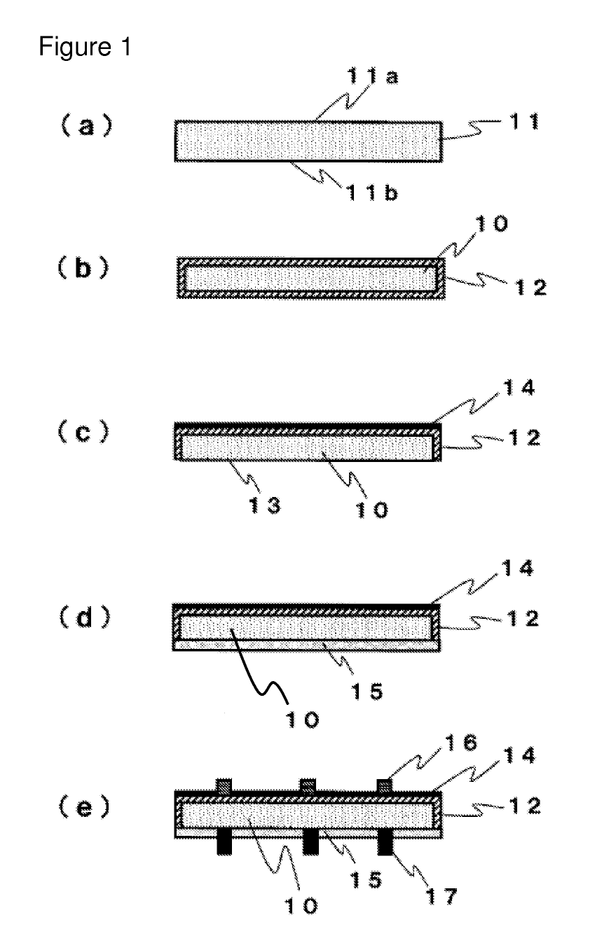

As shown at FIG. 1(a), semiconductor substrate 11 comprising monocrystalline or polycrystalline silicon having one charge carrier type is prepared. For example, p-type substrate employing boron (B) or the like as dopant and having resistivity on the order of 0.2 to 2 Ωcm (ohm-cm) might be favorably used as this semiconductor substrate 11. While n-type substrate which is of n-type may, where the situation warrants, be used as semiconductor substrate 11, the description that follows is given in terms of an example in which p-type substrate is used as semiconductor substrate 11.

When monocrystalline silicon is used as semiconductor substrate 11, ingot is first fabricated using the Czochralski method or other such pulling method. When polycrystalline silicon is used as semiconductor substrate 11, ingot is fabricated using the casting method or the like. Because it permits mass production, polycrystalline silicon is more advantageous than monocrystalline silicon. In the example described below, polycrystalline silicon is used as semiconductor substrate 11.

A wire saw or the like might, for example, be used to slice the polycrystalline silicon ingot to a thickness of not more than 350 μm, and more preferably not more than 200 μm (e.g., 150 μm to 200 μm), to obtain semiconductor substrate 11. To clean layer(s) of contamination from slicing that adhere to the surface of semiconductor substrate 11, it is desirable to use NaOH solution, KOH solution, a solution containing a mixture of hydrofluoric acid solution and fluoronitric acid solution, or the like to etch a very small amount of the surface thereof.

It is preferred that dry etching, wet etching, or the like be employed, or a reactive ion etching (RIE) apparatus or the like be employed, to form a textured (rough) surface structure capable of reducing reflectance of light at the first-principal-plane 11a side of semiconductor substrate 11.

As shown at FIG. 1(b), n-type layer 12 is formed over the entire surface of semiconductor substrate 11. It is preferred that P (phosphorous) be used as doping element, sheet resistance of n-type layer 12 being made to be on the order of 30 Ω/□ (ohm/square) to 150 Ω/□ (ohm/square). This causes a pn junction to be formed between n-type layer 12 and p-type bulk region 10.

Semiconductor substrate 11 might, for example, be placed within an oven heated to on the order of 700° to 900° C., and, while maintaining this temperature, gas-phase thermal diffusion or the like might thereafter be carried out for on the order of 20 to 40 minutes in an environment in which POCl₃ (phosphorus oxychloride) in gas form is used as diffusion source, to form n-type layer 12 of thickness on the order of 0.2 μm (micrometers) to 0.7 μm (micrometers).

As shown at FIG. 1(c), n-type layer 12 formed at the second-principal-plane 11b side of semiconductor substrate 11 is removed, forming surface 13 exposing p-type bulk region 10 at the second-principal-plane 11b side thereof. In this way, p-type bulk region 10 is exposed and what was a region containing a continuous pn junction is divided into sections. Exposed surface 13 might for example be formed by immersing only the second-principal-plane 11b side of semiconductor substrate 11 in fluoronitric acid solution to remove the n-type layer 12 at the n-type-layer 10b side thereof. Semiconductor substrate 11 is thereafter immersed in hydrofluoric acid to remove phosphorous glass formed at the surface of semiconductor substrate 11 during formation of n-type layer 12, and is thereafter cleaned and dried.

Next, this semiconductor substrate 11 is immersed in hydrofluoric acid solution to carry out the hydrogen treatment step. This hydrogen treatment step may also serve as the hydrofluoric acid treatment for removal of the phosphorous glass. The warm water treatment step is thereafter carried out by immersing this in warm water to which acid additive (nitric acid) and alkaline additive (ammonium carbonate) added and which has a pH of not more than 7, and this is thereafter dried. In this way, a semiconductor substrate for a solar cell is prepared which has semiconductor junction regions in the form of pn junction regions and on which a hydrogen treatment step and a warm water treatment step have been carried out.

As described above, a substrate preparation step is carried out in which a semiconductor substrate for a solar cell is prepared which has semiconductor junction regions (pn junction regions in the foregoing example) and on which a method for surface treatment of semiconductor substrate has been carried out.

As shown at FIG. 1(c), antireflective film 14 is formed at the first-principal-plane 11a side thereof. As material for antireflective film 14, SiNx (silicon nitride), TiO₂, SiO₂, MgO, ITO (indium tin oxide), SnO₂, ZnO, or the like may be employed. Thickness of antireflective film 14 is chosen as appropriate depending on material, being such as will permit achievement of nonreflection of incident light as appropriate. For example, for semiconductor substrate 11, this might be made to have a refractive index on the order of 1.8 to 2.3 and a thickness on the order of 500 Å(Angstroms) to 1200 Å (Angstroms). As method for creating antireflective film 14, plasma-enhanced chemical vapor deposition (PECVD), vapor deposition, sputtering, or the like may be employed.

As shown at FIG. 1(d), passivation film 15 is formed at the second-principal-plane 11b side of semiconductor substrate 11. As material for passivation film 15, SiNx (silicon nitride), TiO₂, SiO₂, Al₂O₃, or the like may be employed. As method for creating passivation film 15, PECVD, vapor deposition, sputtering, atomic layer deposition (ALD), or the like may be employed.

A hydrogen treatment step and a warm water treatment step are thus carried out, and antireflective film 14 and/or passivation film 15 is formed on the surface of a semiconductor substrate from which the surface reconstruction layer has been removed, as a result of which reduced surface recombination is made possible, and formation of a solar cell element having high output characteristics is permitted.

A silicon oxide film may be formed prior to formation of antireflective film 14 and passivation film 15. This silicon oxide film may be formed at the surface of the silicon substrate by treating the silicon substrate with nitric acid solution or nitric acid vapor in accordance with the nitric acid oxidation method. By forming a thin silicon oxide film at the surface of the silicon substrate in this way, it is possible to achieve even greater passivation effect. For example, the silicon oxide film may be formed on the surface of the silicon substrate by immersing the silicon substrate within heated nitric acid solution of concentration not less than 60 mass % or keeping the silicon substrate within nitric acid vapor produced by heating nitric acid solution of concentration not less than 60 mass % until it boils.

As shown at FIG. 1(e), electrodes (busbar electrodes and finger electrodes) 16 at the first-principal-plane 11a side and electrodes (busbar electrodes and finger electrodes) 17 at the second-principal-plane 11b side are formed by coating with silver or other such paste in accordance with the screen printing method or the like and then firing. In this way, an electrode formation step is carried out in which output extracting electrodes are formed on the semiconductor substrate.

Because the double-sided-electrode solar cell element fabricated above permits reduction in loss of minority carriers due to surface recombination at the semiconductor substrate, and permits dramatic extension of minority carrier lifetime, it is possible to improve photoelectric conversion efficiency.

Similar effect as at the foregoing double-sided-electrode solar cell element may also be expected for a semiconductor element that is a back-contact-type solar cell element at which electrodes of mutually differing polarity are arranged in rows at the backside of the semiconductor substrate.

As another example of a semiconductor device, a solar cell having a pin junction region will next be described. Description will be given below in terms of an example in which such solar cell is a heterojunction solar cell element.

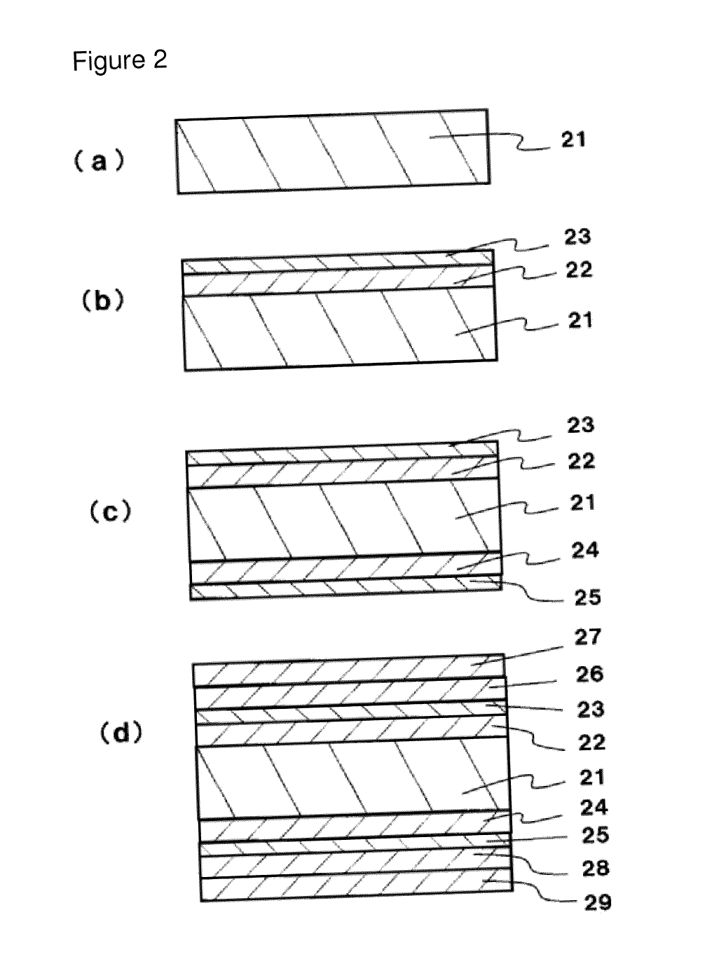

As shown at FIG. 2(a), semiconductor substrate 21 which is 200 μm (micrometers) in thickness and which is silicon substrate comprising monocrystal having n-type charge carriers might, for example, be prepared in similar fashion as at the aforementioned method. This semiconductor substrate 21 is immersed in hydrofluoric acid solution to carry out a hydrogen treatment step. The warm water treatment step is thereafter carried out by immersing semiconductor substrate 21 in warm water which has a pH of not more than 7 and which contains acid additive (e.g., nitric acid) and alkaline additive (e.g., ammonium carbonate), and semiconductor substrate 21 is thereafter dried. In this way, a substrate preparation step is carried out in which a semiconductor substrate for a solar cell is prepared.

Next, a junction region formation step is carried out in which semiconductor junction regions in the form of pin junction regions are formed. First, as shown at FIG. 2(b), a plasma CVD apparatus is used to form i-type hydrogenated amorphous silicon layer 22, and p-type hydrogenated amorphous silicon layer 23 arranged thereabove, at a one principal plane side of a semiconductor substrate 21 on which the foregoing treatment has been carried out.

Next, as shown at FIG. 2(c), a plasma CVD apparatus is used to form i-type hydrogenated amorphous silicon layer 24, and n-type hydrogenated amorphous silicon layer 25 arranged thereabove, at the other principal plane, corresponding to the backside relative to the one principal plane, of semiconductor substrate 21.

Next, an electrode formation step is carried out in which output extracting electrodes are formed on the semiconductor substrate. As shown at FIG. 2(d), a sputter apparatus is used to respectively form transparent electrically conductive layers 26, 28 comprising ITO, ZnO, and/or the like over p-type hydrogenated amorphous silicon layer 23 and n-type hydrogenated amorphous silicon layer 25. Screen printing is used to apply thermosetting electrically conductive paste comprising silver or the like in desired pattern over respective transparent electrically conductive layers 26, 28, and this is thereafter heated to on the order of 150° to 200° C. to form front electrode 27 and back electrode 29.

Because the heterojunction solar cell element fabricated as described above permits reduction in loss of minority carriers due to surface recombination at silicon substrate 1, and permits dramatic extension of minority carrier lifetime, it is possible to improve photoelectric conversion efficiency.

It is preferred that wet treatment of the semiconductor substrate according to the present embodiment be carried out before formation of functional films on the surface of semiconductor substrate. The reason is because this will permit formation of satisfactory junction interface(s) between functional films and semiconductor substrate.

The present invention is not limited to the foregoing embodiments but admits of a great many revisions and variations. For example, although description has been given primarily in terms of examples in which double-sided-electrode solar cell elements and heterojunction solar cell elements serve as solar cell elements, the present invention is not limited to such solar cell elements. Although description has been given in terms of preferred examples in which silicon substrate served as semiconductor substrate, the present invention is not limited to silicon substrate.

The solar cell may for example be a solar cell module which is provided with a plurality of the aforementioned solar cell elements. Where output of a single solar cell element would be small, a solar cell module may be constituted by connecting a plurality of solar cell elements in series or the like. A solar cell module may, for example, comprise as principal components: transparent member(s) made of glass or the like; frontside filler material comprising transparent ethylene-vinyl acetate (EVA) or the like; a plurality of solar cell elements which are such that the electrodes of adjacent solar cell elements are connected by wiring members; backside filler material comprising EVA or the like; and backside protective member at which polyethylene terephthalate (PET) or metal foil is sandwiched between polyvinyl fluoride resin (PVF). Employment of the semiconductor substrate of the present embodiment in such a solar cell module will permit achievement of an excellent solar cell module having higher photoelectric conversion efficiency than was the case conventionally.

### WORKING EXAMPLES

Working examples of the semiconductor substrate will next be described.

First, n-type monocrystalline silicon substrate having a thickness of 300 μm (micrometers) was prepared. A hydrogen treatment step was carried out by immersing the silicon substrate for 5 minutes in a tank containing hydrofluoric acid solution of concentration 0.5% by mass.

Next, acid additive was prepared by adding 0.12 ml of nitric acid of concentration 60 mass % to 100 ml of pure water. Alkaline additive was prepared by adding 0.04 ml of aqueous ammonia of concentration 30 mass % to 100 ml of pure water. Separate from the alkaline additive comprising aqueous ammonia, alkaline additive was prepared which comprised aqueous ammonium carbonate of concentration 0.1 mass %.

Next, 1.4 ml of the foregoing acid additive was added to pure water that had been allowed to boil for 30 minutes, the foregoing alkaline additive was further added thereto so as to cause this to be a prescribed pH, adjustment being carried out so as to obtain warm water of various pH values (pH 4 to pH 7). Samples Nos. 1 through 5 used the alkaline additive comprising aqueous ammonia, and Sample No. 6 used the alkaline additive comprising aqueous ammonium carbonate.

A warm water treatment steps was carried out by immersing silicon substrates for 40 minutes in warm waters having the respective pH values (temperature 98° C.). Thereafter, following drying, a μ-PCD-type lifetime measurement apparatus was used to measure lifetimes T of minority carriers at the silicon substrate (Samples Nos. 1 through 6).

Sample No. 7 was employed as comparative example, lifetime T of minority carriers at silicon substrate which did not undergo the foregoing wet treatment being measured in the same manner as described above.

The foregoing silicon substrates were used to fabricate double-sided-electrode solar cell elements. More specifically, wet etching was used to form a textured surface structure at a first-principal-plane side of the silicon substrate comprising n-type monocrystal. Next, boron atoms were diffused into the silicon substrate to form a p-type layer having sheet resistance on the order of 90 Ω/□ (ohm/square). The p-type layer formed on the second-principal-plane side thereof was removed using fluoronitric acid solution. The boron glass produced at this time was thereafter removed using hydrofluoric acid solution.

Next, after carrying out the warm water treatment step at the respective conditions described above, plasma CVD was used to form an antireflective film and a passivation film, each comprising silicon nitride, at the first-principal-plane side and the second-principal-plane side thereof.

Next, silver paste is applied in the pattern of busbar electrodes and finger electrodes at the first-principal-plane side thereof. Aluminum paste is applied in the pattern of finger electrodes, and silver paste is applied in the pattern of busbar electrodes, at the second-principal-plane side thereof. By thereafter firing these paste patterns, output extracting electrodes were formed to fabricate the solar cell element. The fire-through method was used to cause those electrodes among the electrodes on the first-principal-plane side and those electrodes among the electrodes on the second-principal-plane side that were finger electrodes to respectively be made to contact the semiconductor substrate.

Photoelectric conversion efficiency η of the solar cell elements fabricated as described above was measured and evaluated. These measurements were carried out based on JIS C 8913 under conditions such that air mass (AM) was 1.5 and irradiation was 100 mW/cm².

Results of these measurements are shown in TABLE 1.

TABLE 1

| | | τ | |
|---|---|---|---|
| | | [μsec | η |
| | pH | (microseconds)] | [%] |
| 1 | 4 | 8.7 | 17.08 |
| 2 | 5 | 88.3 | 17.18 |
| 3 | 5.5 | 108.1 | 17.18 |
| 4 | 6 | 139.4 | 17.18 |
| 5 | 7 | 6.5 | 17.06 |
| 6 | 5.5 | 238.4 | 17.18 |
| 7 | — | 2.0 | 16.95 |

As can be seen from the results at TABLE 1, it was observed that lifetimes T at Samples Nos. 1 through 6 for which the warm water had pH values of 4 to 7 were 6.5 μsec (microseconds) to 139.4 μsec (microseconds), which was more than three times longer than the 2.0 μsec (microseconds) at Sample No. 7, which was the comparative example. In particular, it was observed that lifetimes T at Samples Nos. 2 through 5, which were treated with warm water having pH not less than 5 and not more than 6, were 88.3 μsec (microseconds) to 238.4 μsec (microseconds), which was much longer than at Sample No. 7. Upon comparing Sample No. 3 and Sample No. 6, it was observed that use of ammonium carbonate as alkaline additive will result in even greater improvement in lifetime T. It was observed that photoelectric conversion efficiency η at Samples Nos. 1 through 6 was 17.06% to 17.18%, which was high as compared with the 16.95% at Sample No. 7, which was the comparative example.

### Explanation of Reference Numerals

10: p-type bulk region
11, 21: Semiconductor substrate
11a: First principal plane
11b: Second principal plane
12: N-type layer
14: Antireflective film
15: Passivation film
16: First-principal-plane electrode
17: Second-principal-plane electrode
22, 24: i-type hydrogenated amorphous silicon layer
23: p-type hydrogenated amorphous silicon layer
25: n-type hydrogenated amorphous silicon layer
26, 28: Transparent electrically conductive layer
27: Front electrode
29: Back electrode

1-10. (canceled)

11. A method for surface treatment of a semiconductor substrate, the method comprising:
preparing a semiconductor substrate;
adding an acid additive and an alkaline additive to water to obtain an aqueous solution having a pH of not more than 7, comprising no hydrofluoric acid;
hydrogen-terminating a dangling bond at a surface of the semiconductor substrate; and
bringing the surface, at which the dangling bond has been hydrogen-terminated, into contact with the aqueous solution.

12. The method according to claim 11, wherein the semiconductor substrate comprises a crystalline silicon substrate.

13. The method according to claim 11, wherein the hydrogen-terminating is carried out by bringing the surface into contact with a hydrofluoric acid solution.

14. The method according to claim 11, wherein the aqueous solution has a pH of not less than 5 and not more than 6.

15. The method according to claim 11, wherein the aqueous solution has a temperature of not less than 80° C. and less than 100° C.

16. The method according to claim 11, wherein the alkaline additive comprises ammonia.

17. The method according to claim 11, wherein a concentration of the acid additive is not less than 1 ppm and not more than 1000 ppm.

18. A semiconductor substrate on which the method according to claim 11 has been carried out, comprising dangling bonds, which is hydroxyl-terminated, at a surface thereof.

19. A method for manufacturing a solar cell, the method comprising:
preparing a semiconductor substrate on which the method according to claim 11 has been carried out, wherein the semiconductor substrate comprises semiconductor junction region; and
forming an electrode for extracting output on the semiconductor substrate.

20. A method for manufacturing a solar cell, the method comprising:
preparing a semiconductor substrate, on which the method according to claim 11 has been carried out;
forming a semiconductor junction region at the semiconductor substrate; and
forming an electrode for extracting output on the semiconductor substrate.

21. The method according to claim 11, wherein the semiconductor substrate in the preparing procedure comprises an oxide film on the surface thereof.

22. The method according to claim 21, further comprising eliminating the oxide film.

23. The method according to claim 22, wherein the eliminating the oxide film and the hydrogen-terminating the dangling bond are carried out at the same time by bringing the surface into contact with a hydrofluoric acid solution.

24. The method according to claim 11, wherein bringing the surface into contact with the aqueous solution comprises hydroxyl-terminating the dangling bond.

25. The method according to claim 14, wherein the aqueous solution has a pH of not less than 5.5 and not more than 6.

26. The method according to claim 11, wherein the alkaline additive comprises ammonium carbonate.

27. The method according to claim 16, wherein the acid additive comprises one selected from a group consisting of nitric acid, hydrochloric acid, and sulfuric acid.

28. The method according to claim 26, wherein the acid additive comprises one selected from a group consisting of nitric acid, hydrochloric acid, and sulfuric acid.
